(19) United States
(12) Patent Application Publication
(10) Pub. No.: US 2025/0054847 A1
(43) Pub. Date: Feb. 13, 2025

(54) WIRING BOARD AND SEMICONDUCTOR DEVICE

(71) Applicant: SHINKO ELECTRIC INDUSTRIES CO., LTD., Nagano-shi (JP)

(72) Inventor: Kensuke Uchida, Nagano (JP)

(21) Appl. No.: 18/798,016

(22) Filed: Aug. 8, 2024

(30) Foreign Application Priority Data
Aug. 10, 2023 (JP) 2023-131514

(51) Int. Cl. H01L 23/498; H01L 21/48; H01L 23/00

(52) U.S. Cl. CPC H01L 23/49822; H01L 23/49811; H01L 23/49838; H01L 24/16; H01L 21/4857; H01L 23/49866; H01L 24/32; H01L 24/73; H01L 2224/16227; H01L 2224/32225; H01L 2224/73204

(57) ABSTRACT

A wiring board includes an insulating layer and a connection terminal that is formed on a surface of the insulating layer. The connection terminal includes a metal pad that is embedded in the insulating layer and a plated layer that covers an end face of the pad that is exposed on the surface of the insulating layer. The end face of the pad is depressed in a concave surface form to a position lower than the surface of the insulating layer and a surface of the plated layer on a side opposite to a surface making contact with the end face of the pad is depressed in the concave surface form toward the end face.

### CROSS-REFERENCE TO RELATED APPLICATION

This application is based upon and claims the benefit of priority of the prior Japanese Patent Application No. 2023-131514, filed on Aug. 10, 2023, the entire contents of which are incorporated herein by reference.

### FIELD

The embodiments discussed herein are related to a wiring board and a semiconductor device.

### BACKGROUND

In general, terminals for connection to a semiconductor chip are formed on a wiring board on which the semiconductor chip is mounted. The connection terminals are formed, for example, on the outermost layer of the wiring board and the semiconductor chip is joined with solder to the connection terminals that are formed on the outermost layer of the wiring board.

Specifically, for example, pads made of metal, such as copper, are embedded in an insulating layer that forms the outermost layer of the wiring board, so that the connection terminals are formed. An end face of the pad of the connection terminal is a flat surface that is exposed from the surface of the insulating layer and the end face is flush with the surface of the insulating layer. Solder is supplied to the connection terminals and the connection terminals of the wiring board and the electrodes of the semiconductor chip are joined via the solder.

Patent Literature 1: Japanese Laid-open Patent Publication No. 2012-104774

As for the connection terminals of the wiring board described above, the end face of the pad that is exposed from the surface of the insulating layer is sometimes covered with a plated layer made of metal, such as nickel, for the purpose of increasing wettability of the solder, or the like. The plated layer is formed by, for example, electroless plating.

The connection terminal in which the end face of the pad is covered with the plated layer however has a problem in that, when the connection terminal is joined to a semiconductor chip, solder sometimes causes a solder bridge in which conduction is made between the connection terminal and an adjacent connection terminal. In other words, when the plating layer in the connection terminal is formed by electroless plating, metal, such as nickel, isotropically precipitates and grows at the end face of the pad and the plated layer protrudes upward spherically from the end face of the pad. For this reason, when solder for joining the semiconductor chip to the connection terminal is supplied, the solder sometimes flows out of the plated layer along the spherical plated layer and extends laterally to the connection terminal. As a result, adjacent connection terminals easily make conduction via solder and there is a risk that a solder bridge may occur.

### SUMMARY

According to an aspect of an embodiment, a wiring board includes an insulating layer; and a connection terminal that is formed on a surface of the insulating layer, wherein the connection terminal includes a metal pad that is embedded in the insulating layer; and a plated layer that covers an end face of the pad that is exposed on the surface of the insulating layer, the end face of the pad is depressed in a concave surface form to a position lower than the surface of the insulating layer, and a surface of the plated layer on a side opposite to a surface making contact with the end face of the pad is depressed in the concave surface form toward the end face.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring board according to a first embodiment;

FIG. 2 is a flowchart illustrating a method of manufacturing a semiconductor device according to the first embodiment;

FIG. 3 is a diagram illustrating a specific example of a core board forming process;

FIG. 4 is a diagram illustrating a specific example of a build-up process;

FIG. 5 is a diagram illustrating a specific example of a solder resist layer forming process;

FIG. 6 is a diagram illustrating a specific example of a connection terminal forming process;

FIG. 7 is a diagram illustrating a specific example of a semiconductor chip mounting process;

FIG. 8 is a flowchart illustrating a connection terminal forming process according to the first embodiment;

FIG. 9 is a diagram illustrating part of an interconnection layer in an enlarged manner;

FIG. 10 is a diagram illustrating a specific example of a first insulating layer forming process;

FIG. 11 is a diagram illustrating a specific example of a seed layer forming process;

FIG. 12 is a diagram illustrating a specific example of a resist layer forming process;

FIG. 13 is a diagram illustrating a specific example of an electrolytic plating process;

FIG. 14 is a diagram illustrating a specific example of a resist layer removal process;

FIG. 15 is a diagram illustrating a specific example of a second insulating layer layering process;

FIG. 16 is a diagram illustrating a specific example of a second insulating layer polishing process;

FIG. 17 is a diagram illustrating a specific example of a pad polishing process;

FIG. 18 is a diagram illustrating a specific example of a plated layer forming process;

FIG. 19 is a diagram illustrating a configuration of a wiring board according to a modification of the first embodiment;

FIG. 20 is a diagram illustrating a configuration of a wiring board according to a second embodiment;

FIG. 21 is a flowchart illustrating a connection terminal forming process according to the second embodiment;

FIG. 22 is a diagram illustrating a specific example of an outermost insulating layer forming process;

FIG. 23 is a diagram illustrating a specific example of a seed layer forming process;

FIG. 24 is a diagram illustrating a specific example of an electrolytic plating process;

FIG. 25 is a diagram illustrating a specific example of a metal layer polishing process;

FIG. 26 is a diagram illustrating a specific example of a plated layer forming process;

FIG. 27 is a diagram illustrating a configuration of a connection terminal according to modifications of the first embodiment and the second embodiment; and

FIG. 28 is a diagram illustrating a configuration of a connection terminal according to modifications of the first embodiment and the second embodiment.

### DESCRIPTION OF EMBODIMENTS

Embodiments of a wiring board and a semiconductor device disclosed herein will be described in detail below with reference to the accompanying drawings. Note that the embodiments do not limit the disclosed technique.

### First Embodiment

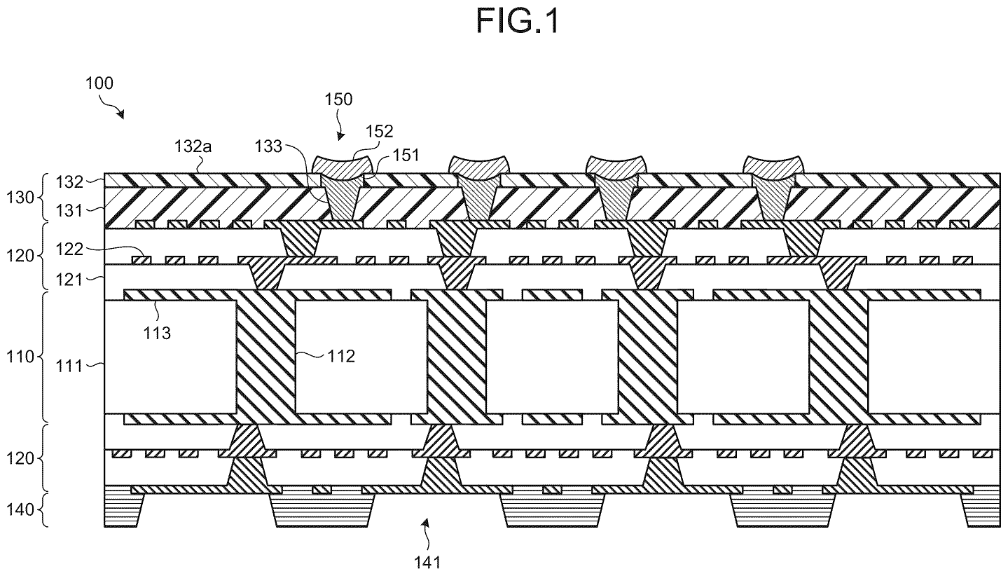

FIG. 1 is a diagram illustrating a configuration of a wiring board 100 according to a first embodiment. FIG. 1 schematically illustrates a cross-section of the wiring board 100. The wiring board 100 illustrated in FIG. 1 is usable as a board of a semiconductor device on which a semiconductor chip is mounted.

The wiring board 100 is a layered structure and includes a core board 110, a multilayer interconnection structure 120, an outermost insulating layer 130, and a solder resist layer 140. It will be described below that, as illustrated in FIG. 1, the solder resist layer 140 is the lowest layer and the outermost insulating layer 130 is the top layer; however, the wiring board 100, for example, may be used upside down and may be used in any posture.

In the core board 110, interconnection layers 113 are formed by plating on both surfaces of a substrate 111 that is a platy insulator. The interconnection layers 113 on both surfaces are connected as required via through interconnections 112.

In the multilayer interconnection structure 120, layers including an insulating layer 121 that is insulating and an interconnection layer 122 that is conductive are layered. The insulating layer 121 is formed, for example, using insulating resin, such as epoxy resin or polyimide resin. The interconnection layer 122 is formed, for example, using metal, such as copper. In FIG. 1, two layers are layered in the multilayer interconnection structure 120 above the core board 110 and two layers are layered in the multilayer interconnection structure 120 under the core board 110; however, the number of layers to be layered may be one or three or more.

The outermost insulating layer 130 is a layer that covers the interconnection layer 122 on the surface of the multilayer interconnection structure 120. The outermost insulating layer 130 is formed, for example, using insulating photosensitive resin, such as acrylic resin and polyimide resin. The outermost insulating layer 130 may be formed, for example, using insulating non-photosensitive resin, such as epoxy resin.

The outermost insulating layer 130 is a double-layered structure and has a first insulating layer 131 and a second insulating layer 132. The first insulating layer 131 covers the interconnection layer 122 on the surface of the multilayer interconnection structure 120. The second insulating layer 132 is layered above the first insulating layer 131 adjacently.

The side of the outermost insulating layer 130 of the wiring board 100 is a face on which electronic parts, such as a semiconductor chip, are mounted. In a position in which a semiconductor chip is mounted, an opening 133 is formed in the first insulating layer 131 of the outermost insulating layer 130. In the case where the outermost insulating layer 130 is formed using photosensitive resin, it is possible to form the opening 133 by exposure and development. When the outermost insulating layer 130 is formed using non-photosensitive resin, it is possible to form the opening 133 by laser processing.

A connection terminal 150 that connects the interconnection layer 122 of the multilayer interconnection structure 120 and an electrode of the semiconductor chip is formed in the opening 133 of the first insulating layer 131 of the outermost insulating layer 130. The connection terminal 150 is a bump electrode that is formed such that the connection terminal 150 is raised from a surface 132a of the outermost insulating layer 130 and includes a pad 151 and a plated layer 152.

The pad 151 is an electrode serving as the main part of the connection terminal 150 and is embedded in the outermost insulating layer 130 (that is, the first insulating layer 131 and the second insulating layer 132). The pad 151 is formed in the opening 133 of the first insulating layer 131 by, for example, copper (Cu) electrolytic plating and is connected to the interconnection layer 122 of the multilayer interconnection structure 120 and protrudes upward from the opening 133 of the first insulating layer 131, and is embedded in the second insulating layer 132 in a portion of the protrusion. An end face (upper surface) of the pad 151 is exposed on the surface 132a of the outermost insulating layer 130, that is, the surface 132a of the second insulating layer 132. The end face of the pad 151 is depressed in a concave surface form to a position lower than the surface 132a of the second insulating layer 132 and the periphery of the end face of the pad 151 is higher than the center.

The plated layer 152 is a metal layer that covers the end face of the pad 151 that is exposed on the surface 132a of the second insulating layer 132. It is possible to form the plated layer 152 by, for example, non-electrolytic plating using, metal, such as nickel (Ni) as a material.

In the first embodiment, because the plated layer 152 is formed along the end face of the pad 151 that is depressed in the concave surface form, the upper surface of the plated layer 152 is depressed in the concave surface form toward the end face of the pad 151 in the concave surface form. Accordingly, the periphery of the upper surface of the plated layer 152 is higher than the center. For this reason, when solder for joining the semiconductor chip to the connection terminal 150 is supplied, the solder is supplemented on the end face of the plated layer 152 that is depressed in the concave surface form and a flow-out of the solder to the outside of the plated layer 152 tends not to occur. As a result, the connection terminals 150 that are adjacent to each other tend not to make conduction via the solder, which makes it possible to inhibit occurrence of a solder bridge caused by the solder.

In the first embodiment, the periphery of the end face of the pad 151 is positioned on the same plane as that of the surface 132a of the second insulating layer 132. Accordingly, the end face of the pad 151 and the surface 132a of the second insulating layer 132 that is positioned around the end face of the pad 151 are continuously covered with the plated layer 152. This increases the strength of adhesion between the plated layer 152 and the end face of the pad 151, which makes it possible to inhibit the plated layer 152 from peeling from the end face of the pad 151.

In the first embodiment, the end face of the pad 151 makes contact with the second insulating layer 132 at the periphery. This increases the strength of adhesion between the pad 151 and the second insulating layer 132, which makes it possible inhibit the pad 151 from peeling off the second insulating layer 132.

The case where the periphery of the end face of the pad 151 is positioned on the same plane as that of the surface 132a of the second insulating layer 132 has been described; however, the periphery of the end face of the pad 151 may be positioned in a position lower than the surface 132a of the second insulating layer 132. Accordingly, compared to the case where the periphery of the end face of the pad 151 is positioned on the same plane as that of the surface 132a of the second insulating layer 132, the level of the end face of the pad 151 with respect to the surface 132a of the second insulating layer 132 is low. For this reason, the upper surface of the plated layer 152 is depressed deeper in the concave surface form toward the end face of the pad 151 in the concave surface form and, in the case where solder for joining the semiconductor chip to the connection terminal 150 is supplied, a flow-out of the solder to the outside of the plated layer 152 further tends not to occur. As a result, the connection terminals 150 that are adjacent to each other tend not to make conduction via the solder, which makes it possible to further inhibit occurrence of a solder bridge caused by the solder.

The solder resist layer 140 is a layer that covers the interconnection layer 122 on the surface of the multilayer interconnection structure 120 and that protects the interconnection. The solder resist layer 140 is a layer, for example, made of insulating photosensitive resin, such as acrylic resin and polyimide resin, and is one of insulating layers. Note that the solder resist layer 140 may be formed, for example, using insulating non-photosensitive resin, such as epoxy resin.

The side of the solder resist layer 140 of the wiring board 100 is a face that is connected to external parts or an external device. In a position in which an external connection terminal that is electrically connected to an external part or device is formed, an opening 141 is formed in the solder resist layer 140 and the interconnection layer 122 of the multilayer interconnection structure 120 is exposed from the opening 141. For example, an external connection terminal, such as a solder ball, is formed in the opening 141. In the case where the solder resist layer 140 is formed using photosensitive resin, it is possible to form the opening 141 by exposure and development. When the solder resist layer 140 is formed using non-photosensitive resin, it is possible to form the opening 141 by laser processing.

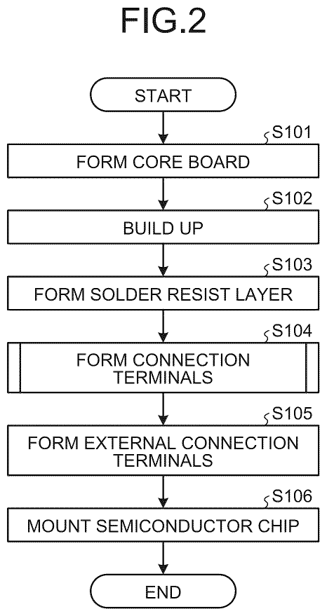

A method of manufacturing a semiconductor device including the wiring board 100 that is configured as described above will be described next with reference to FIG. 2, taking an example specifically. FIG. 2 is a flowchart illustrating a method of manufacturing the semiconductor device according to the first embodiment.

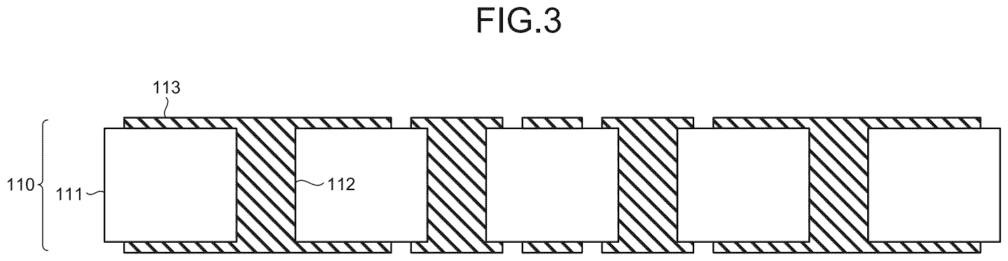

First of all, the core board 110 serving as a support member of the wiring board 100 is formed (step S101). Specifically, for example, as illustrated in FIG. 3, a through interconnection 112 that penetrates the substrate 111 that is a platy insulator is formed in the substrate 111 and the interconnection layers 113 of metal, such as copper or copper alloy, are formed on both the surfaces of the substrate 111 using copper foil or by copper plating. FIG. 3 is a diagram illustrating a specific example of the core board forming step. The interconnection layers 113 on both the surfaces of the substrate 111 are connected as required, for example, via the through interconnection 112 that is formed by plating using metal, such as copper or copper alloy. It is possible to use, as the substrate 111, for example, one obtained by impregnating a reinforcing member, such as glass woven fabric, with insulating resin, such as epoxy resin. It is possible to use, as the reinforcing member, glass non-woven fabric, aramid woven fabric, or aramid non-woven fabric, other than glass woven fabric. It is possible to use, as the insulating resin, polyimide resin or cyanate resin, other than epoxy resin. The through interconnection 112, for example, may be a through-hole that is formed by being filled with thermosetting resin, such as epoxy resin.

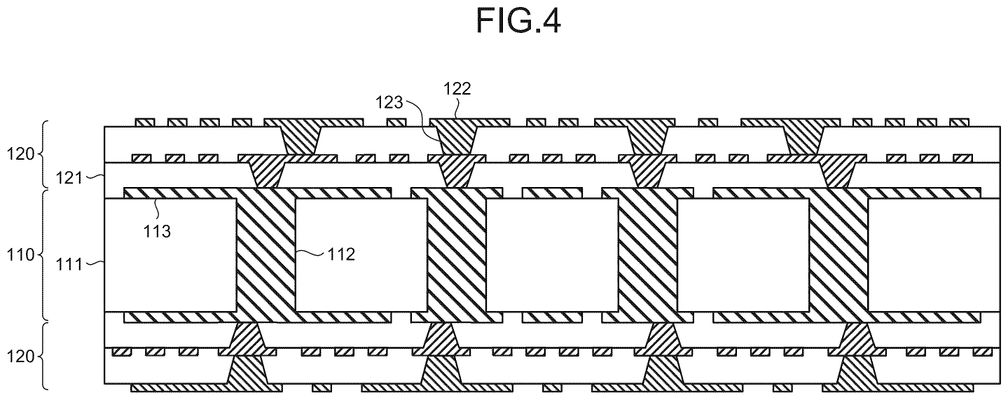

The multilayer interconnection structures 120 are formed on an upper surface and a lower surface of the core board 110 by a build-up technique (step S102). Specifically, for example, as illustrated in FIG. 4, the insulating layers 121 are formed on the upper surface and the lower surface of the core board 110 and the interconnection layers 122 are formed on the surfaces of the insulating layers 121. FIG. 4 is a diagram illustrating a specific example of a build-up process. The insulating layer 121, for example, is formed using insulating resin, such as epoxy resin or polyimide resin. The interconnection layer 122, for example, is formed by plating of metal, such as copper.

For example, a via 123 that is formed by plating of metal, such as copper, connects the interconnection layer 113 of the core board 110 and the interconnection layer 122 or the interconnection layers 122 of adjacent layers as required. A plurality of the insulating layers 121 and a plurality of the interconnection layers 122 may be layered on each of the upper surface and the lower surface of the core board 110.

After the multilayer interconnection structure 120 is formed, the interconnection layer 122 on the surface of the multilayer interconnection structure 120 is covered with the solder resist layer 140 (step S103). For example, the interconnection layer 122 on the surface of the multilayer interconnection structure 120 that is layered on the lower surface of the core board 110 is covered with the solder resist layer 140.

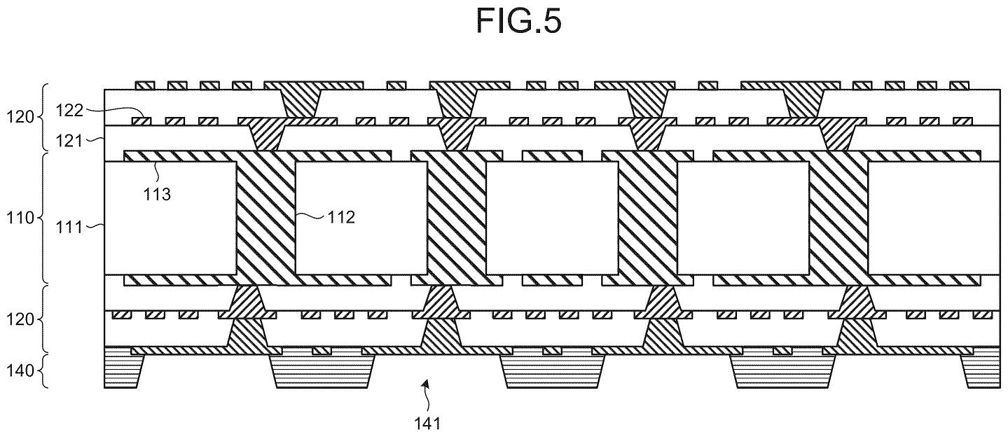

For example, as illustrated in FIG. 5, the openings 141 is then formed in a position in which the external connection terminal is arranged in the solder resist layer 140 on the side of connection to external parts or an external device. FIG. 5 is a diagram illustrating a specific example of a solder resist layer forming process. The interconnection layer 122 on the surface of the multilayer interconnection structure 120 is exposed to bottom surfaces of the openings 141. When photosensitive resin is used as the solder resist layer 140, it is possible to form the openings 141 by exposure and development. When non-photosensitive resin is used as the solder resist layer 140, it is possible to form the openings 141 by laser processing.

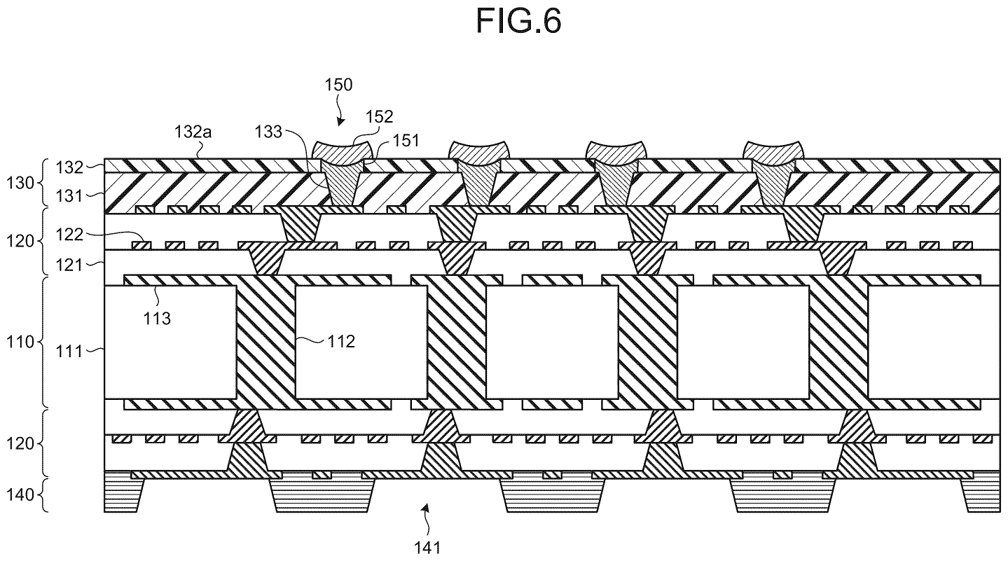

The interconnection layer 122 on the surface of the multilayer interconnection structure 120 is covered with the outermost insulating layer 130 and the connection terminals 150 that are raised from the surface 132a of the outermost insulating layer 130 are formed (step S104). In other words, for example, as illustrated in FIG. 6, the connection terminal 150 including the pad 151 that is embedded in the outermost insulating layer 130 and the plated layer 152 that covers the end face of the pad 151 that is exposed on the surface 132a of the outermost insulating layer 130 is formed. FIG. 6 is a diagram illustrating a specific example of a connection terminal forming process. The pad 151, for example, is formed in the opening 133 of the first insulating layer 131 by copper (Cu) electrolytic plating. It is possible to form the plated layer 152 by, for example, non-electrolytic plating of, metal, such as nickel (Ni). In the connection terminal 150, the end face (upper surface) of the pad 151 is depressed in the concave surface form to the position lower than the surface 132a of the outermost insulating layer 130 and the upper surface of the plated layer 152 is depressed in the concave surface form toward the end face of the pad 151 in the concave surface form. Note that a process of forming the connection terminals 150 will be described in detail below.

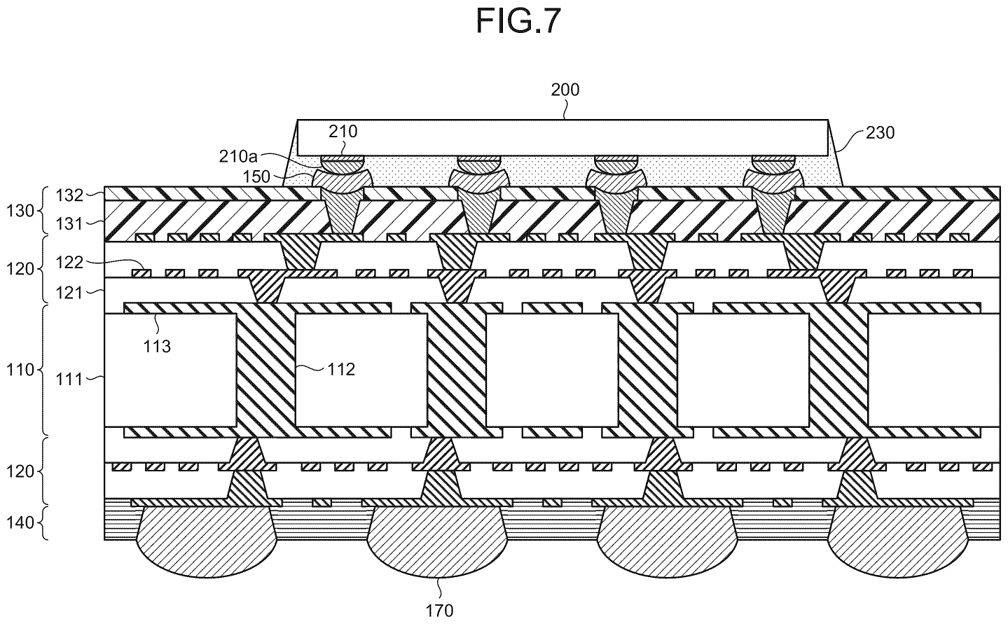

After the connection terminals 150 are formed on the side of the outermost insulating layer 130, the external connection terminals are formed on the side of the solder resist layer 140 (step S105). The semiconductor chip is mounted on the side of the outermost insulating layer 130 (step S106) and the connection terminals 150 and the electrodes of the semiconductor chip are connected. Specifically, for example, as illustrated in FIG. 7, an external connection terminal, such as a solder ball 170, is formed in the opening 141 of the solder resist layer 140. A semiconductor chip 200 is mounted above the connection terminals 150 and electrodes 210 of the semiconductor chip 200 are joined to the connection terminals 150 with solder 210a that is supplied to the plated layer 152. At that time, because the upper surface of the plated layer 152 is depressed in the concave surface form toward the end face of the pad 151 in the concave form, the solder 210a that is supplied is supplemented on the upper surface of the plated layer 152 depressed in the concave form and a flow-out of the solder 210a to the outside of the plated layer 152 tends not to occur. As a result, the connection terminals 150 that are adjacent to each other tend not to make conduction via the solder 210a, which makes it possible to inhibit occurrence of a solder bridge caused by the solder 210a. FIG. 7 is a diagram illustrating a specific example of a semiconductor chip mounting process.

The joint between the electrode 210 and the connection terminal 150 is sealed by underfill resin 230 and a semiconductor device in which the semiconductor chip 200 is mounted on the wiring board 100 completes. Note that the above-described process of forming external connection terminals and the process of mounting a semiconductor chip may be in the inverse order. In other words, after the semiconductor chip 200 is mounted on the wiring board 100, the external connection terminals, such as the solder balls 170, may be formed in the openings 141 of the solder resist layer 140.

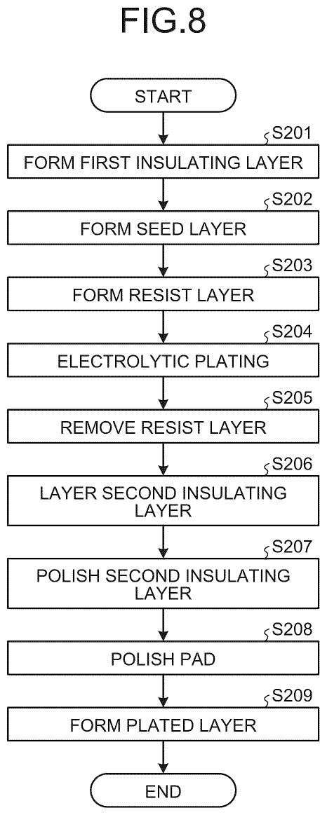

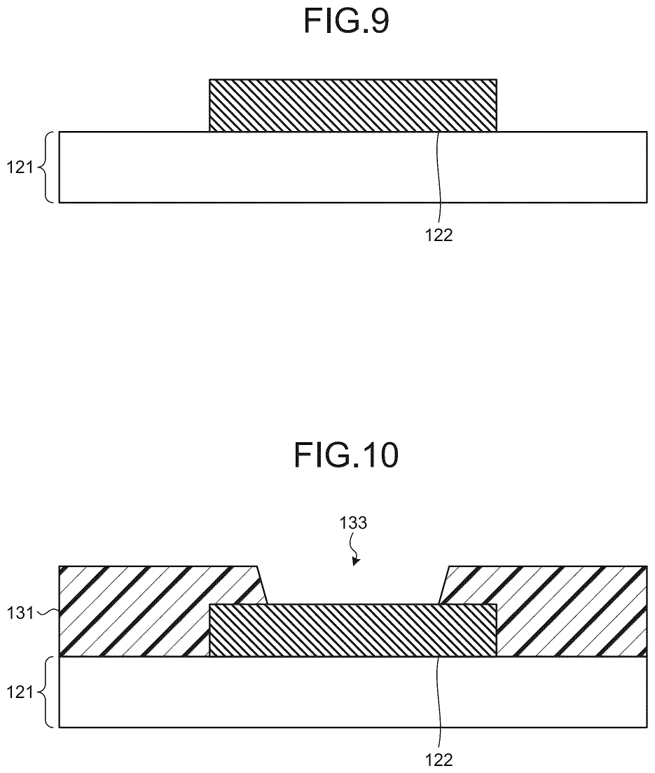

The process of forming the connection terminals 150 will be described next more specifically with reference to FIG. 8. FIG. 8 is a flowchart illustrating the connection terminal forming process according to the first embodiment. For example, the case where the outermost insulating layer 130 and the connection terminals 150 are formed on the interconnection layer 122 that is the top layer of the multilayer interconnection structure 120 as illustrated in FIG. 9 will be described here. FIG. 9 is a diagram illustrating part of an interconnection layer in an enlarged manner.

After the multilayer interconnection structure 120 is layered on the upper surface of the core board 110, the interconnection layer 122 that is the top layer of the multilayer interconnection structure 120 is covered with the first insulating layer 131 (step S201). For example, as illustrated in FIG. 10, the opening 133 is formed in the first insulating layer 131. FIG. 10 is a diagram illustrating a specific example of the first insulating layer forming process. When the outermost insulating layer 130 is formed using photosensitive resin, it is possible to form the opening 133 by exposure and development. When the outermost insulating layer 130 is formed using non photosensitive resin, it is possible to form the opening 133 by laser processing. The interconnection layer 122 is exposed on the bottom surface of the opening 133. The thickness of the first insulating layer 131 is, for example, around 20 to 40 μm.

In this state, a seed layer is formed on the surface of the first insulating layer 131 (step S202). In other words, for example, as illustrated in FIG. 11, a seed layer 301 is formed on the surface of the first insulating layer 131 and over the surface of the interconnection layer 122 that is exposed in the opening 133 by, for example, electroless copper plating or copper sputtering. FIG. 11 is a diagram illustrating a specific example of a seed layer forming process. The thickness of the seed layer 301 is, for example, around 0.01 to 0.4 μm.

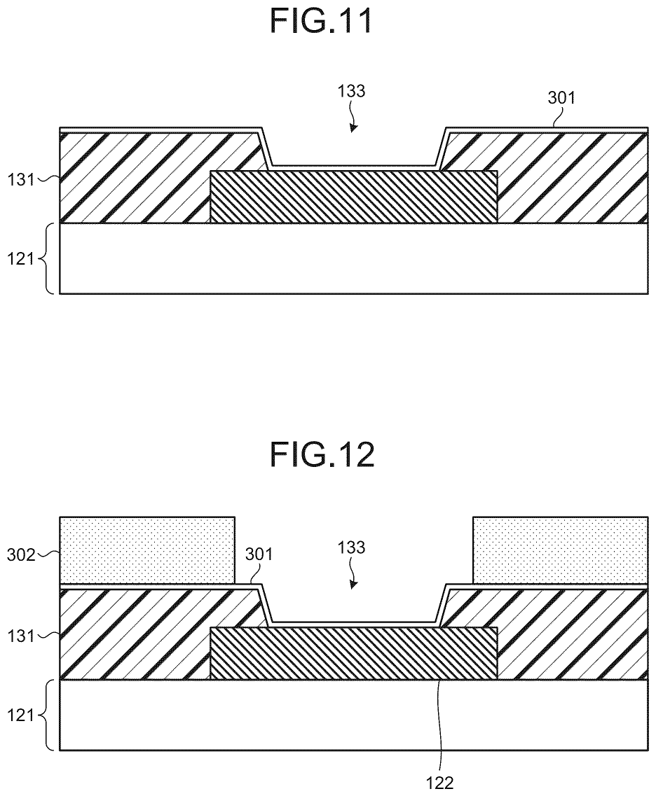

After the seed layer 301 is formed, a resist layer serving as a mask of electrolytic plating is formed on a surface of the seed layer 301 (step S203). In other words, a dry film resist (DFR) made of photosensitive resin is formed on the seed layer 301. Exposure and development corresponding to positions of the connection terminals 150 are performed on the layered DFR and accordingly, for example, as illustrated in FIG. 12, a resist layer 302 is formed on the seed layer 301 in portions excluding the positions in which the connection terminals 150 are formed. FIG. 12 is a diagram illustrating a specific example of a resist layer forming process.

For example, electrolytic plating is performed and accordingly the pads 151 are formed on the seed layer 301 (step S204). Specifically, for example, electrolytic copper plating is performed using a copper sulfate plating solution and accordingly copper precipitates in portions in which the resist layer 302 is not formed and, for example, as illustrated in FIG. 13, the pads 151 are formed on the seed layer 301. At that time, the openings 133 are filled with the pads 151. FIG. 13 is a diagram illustrating a specific example of an electrolytic plating process.

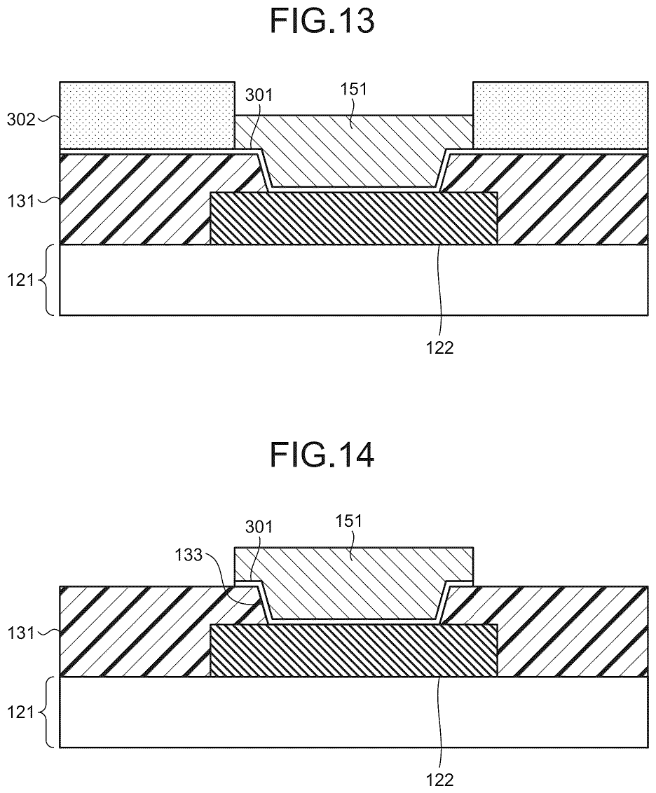

After the pads 151 are formed, the resist layer 302 is removed (step S205). To remove the resist layer 302, for example, caustic soda and an amine alkali stripping solution are used. Flash etching is also performed and the seed layer 301 in portions that are not plated is removed. Accordingly, for example, as illustrated in FIG. 14, the pads 151 that protrude from the openings 133 of the first insulating layer 131 and that connect to the interconnection layer 122 via the seed layer 301 are formed. FIG. 14 is a diagram illustrating a specific example of the resist layer removal process. The thickness of the pads 151 (the height from the upper surface of the first insulating layer 131) can be, for example, around 3 to 20 μm.

After the resist layer 302 is removed, for example, as illustrated in FIG. 15, the second insulating layer 132 that covers the pads 151 is layered on the first insulating layer 131 (step S206). FIG. 15 is a diagram illustrating a specific example of a second insulating layer layering process. The thickness of the second insulating layer 132 is, for example, around 10 to 45 μm.

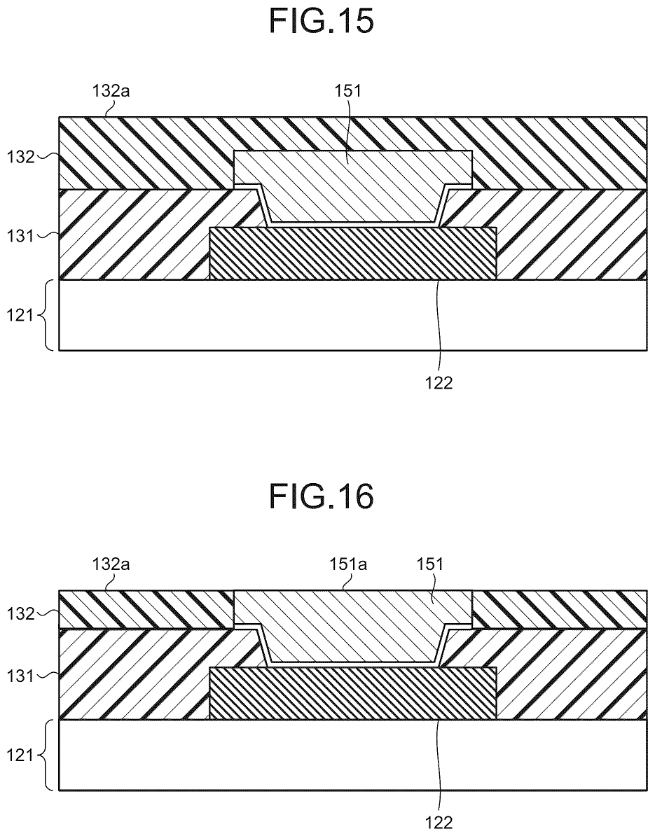

The second insulating layer 132 is entirely polished from the surface 132a of the second insulating layer 132, for example, by chemical mechanical polishing (CMP) (step S207). Specifically, for example, the second insulating layer 132 is polished until the surface 132a of the second insulating layer 132 is flush with the end faces (upper surfaces) 151a of the pads 151 as illustrated in FIG. 16 and the end faces 151a of the pads 151 are exposed on the surface 132a of the second insulating layer 132. Because of the preceding process, the outermost insulating layer 130 including the first insulating layer 131 and the second insulating layer 132 is obtained and the pads 151 that are embedded in the outermost insulating layer 130 (that is, the first insulating layer 131 and the second insulating layer 132) are obtained. FIG. 16 is a diagram illustrating a specific example of a second insulating layer polishing process.

After the second insulating layer 132 is polished, the end faces 151a of the pads 151 that are exposed on the surface 132a of the second insulating layer 132 are polished by, for example, CMP (step S208). Specifically, for example, the end faces of the pads 151 are polished by CMP using a chemical polishing solution, such as a hydrogen peroxide solution. Accordingly, for example, as illustrated in FIG. 17, the end faces 151a of the pads 151 that are exposed on the surface 132a of the second insulating layer 132 are depressed in the concave surface form to positions lower than the surface 132a of the second insulating layer 132. FIG. 17 is a diagram illustrating a specific example of a pad polishing process. The periphery of the end face 151a of the pad 151 is on the same plane as that of the surface 132a of the second insulating layer 132. The end face 151a of the pad 151 makes contact with the second insulating layer 132 at the periphery. The deepest portion of the end face 151a of the pad 151 may be positioned below the upper surface of the first insulating layer 131. In other words, the pad 151 may have the end face 151a that is depressed to a position closer to the interconnection layer 122 than to the surface of the first insulating layer 131.

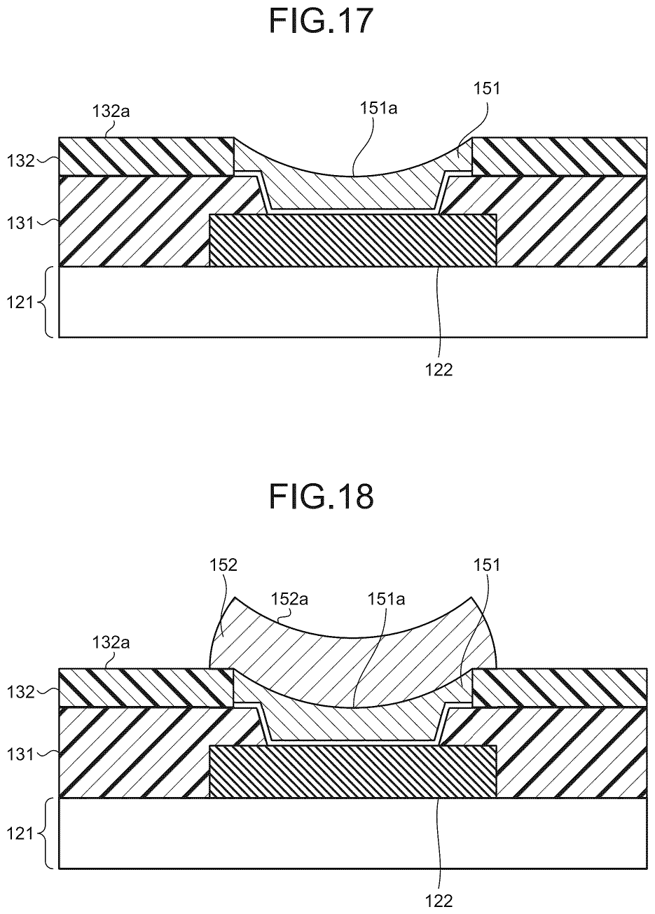

After the pads 151 are polished, for example, as illustrated in FIG. 18, the plated layer 152 that covers the end face 151a of the pads 151 is formed, for example, by non-electrolytic plating using, metal, such as nickel (Ni), as a material (step S209). Accordingly, the connection terminal 150 that connects to the interconnection layer 122 that is the top layer of the multilayer interconnection structure 120 and that includes the pad 151 and the plated layer 152 is formed. FIG. 18 is a diagram illustrating a specific example of a plated layer forming process. The thickness of the plated layer 152 can be, for example, around 1 μm to 10 μm.

In formation of the plated layer 152, metal, such as nickel, isotropically precipitates and grows on the end face 151a of the pad 151. The plated layer 152 thus is formed along the end face 151a of the pad 151 that is depressed in the concave surface form and an upper surface 152a of the plated layer 152 is depressed in the concave surface form toward the end face 151a of the pad 151 in the concave surface form. Accordingly, when the semiconductor chip 200 is mounted, the solder 210a that is supplied to the plated layer 152 of the connection terminal 150 is supplemented on the upper surface 152a of the plated layer 152 that is depressed in the concave surface form and a flow-out of the solder 210a to the outside of the plated layer 152 tends not to occur. As a result, the connection terminals 150 that are adjacent to each other tend not to make conduction via the solder 210a, which makes it possible to inhibit occurrence of a solder bridge caused by the solder 210a.

In formation of the plated layer 152, metal, such as nickel, precipitates and grows not only on the end faces 151a of the pads 151 but also on the surface 132a of the second insulating layer 132 that is positioned around the end faces 151a of the pads 151. The periphery of the end faces 151a of the pads 151 are positioned on the same plane as that of the surface 132a of the second insulating layer 132 and therefore the plated layer 152 is formed also on the surface 132a of the second insulating layer 132 over the periphery of the end faces 151a of the pads 151. For this reason, the plated layer 152 is formed astride the second insulating layer 132 and the pad 151 in a plane view. In other words, the side surface of the plated layer 152 is positioned outward with respect to the periphery of the end face 151a of the pad 151. Accordingly, the end face 151a of the pad 151 and the surface 132a of the second insulating layer 132 that is positioned around the end face of the pad 151 are continuously covered with the plated layer 152. This increases the strength of adhesion between the plated layer 152 and the end face of the pad 151, which makes it possible to inhibit the plated layer 152 from peeling from the end face 151a of the pad 151.

As described above, the wiring board (the wiring board 100 serving as an example) according to the first embodiment includes the insulating layer (the outermost insulating layer 130 serving as an example) and the connection terminal (the connection terminal 150 serving as an example) that is formed on the surface (the surface 132a serving as an example) of the insulating layer. The connection terminal includes the metal pad (the pad 151 serving as an example) that is embedded in the insulating layer and the plated layer (the plated layer 152 serving as an example) that covers the end face (the end face 151a serving as an example) of the pad that is exposed on the surface of the insulating layer. The end face of the pad is depressed in the concave surface form to a position lower than the surface of the insulating layer and the surface (the upper surface 152a serving as an example) of the plated layer on the side opposite to the surface making contact with the end face of the pad is depressed in the concave surface form toward the end face. This makes it possible to inhibit occurrence of a solder bridge caused by the solder (the solder 210a serving as an example).

The end face of the pad may have a periphery that is positioned on the same plane as that of the surface of the insulating layer. This makes it possible to inhibit the plated layer from peeling from the end face of the pad.

The end face of the pad may have a periphery that is positioned in a position lower than the surface of the insulating layer. This makes it possible to inhibit occurrence of a solder bridge caused by the solder.

The end face of the pad may make contact with the insulating layer at the periphery. This makes it possible to inhibit the pad from peeling from the insulating layer.

The insulating layer may include the first insulating layer (the first insulating layer 131 serving as an example) and the second insulating layer (the second insulating layer 132 serving as an example) that is layered on the first insulating layer. The first insulating layer may cover the interconnection layer (the interconnection layer 122 serving as an example) and the opening (the opening 133 serving as an example) that penetrates to the interconnection layer. The pad may be formed in the opening of the first insulating layer and may connect to the interconnection layer, may protrude from the opening of the first insulating layer, and may be embedded in the second insulating layer in a portion of the protrusion. The insulating layer thus is a double-layered structure and therefore it is possible to increase the strength of adhesion between the pad and the insulating layer.

### Modification of First Embodiment

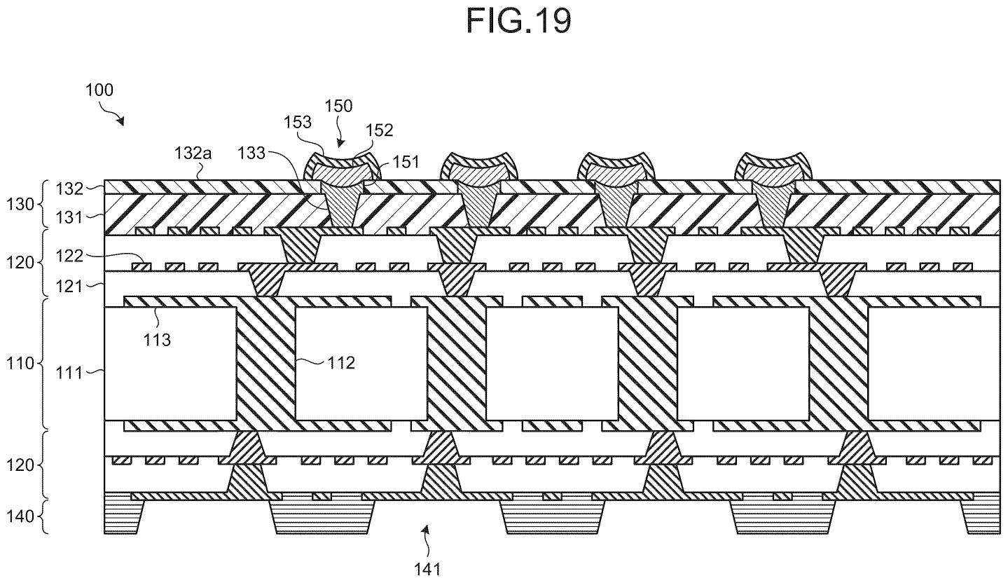

FIG. 19 is a diagram illustrating a configuration of the wiring board 100 according to a modification of the first embodiment. In the modification, the same parts as those of the first embodiment are denoted with the same reference numerals and redundant description thus will be omitted.

As illustrated in FIG. 19, the wiring board 100 according to the modification is different from the first embodiment in that the connection terminal 150 includes a surface processed layer 153. The surface processed layer 153 is a metal layer that covers the upper surface and a side surface of the plated layer 152. Specifically, although illustrated in the drawing is omitted, the surface processed layer 153 includes a palladium (Pd) layer and a gold (Au) layer in sequence from a side close to the plated layer 152 of nickel (Ni). It is possible to form each of the Pd layer and the Au layer by, for example, electrolytic plating or electroless plating. The thicknesses of each of the Pd layer and the Au layer can be around 0.01 to 0.5 μm. An Au layer that is a single layer may be used instead of the Pd-Au layer as the surface processed layer 153.

In formation of the surface processed layer 153, palladium and gold isotropically precipitate and grow on the upper surface and the side surface of the plated layer 152. Accordingly, the surface processed layer 153 is formed along the upper surface that is depressed in the concave surface form of the plated layer 152 and the upper surface of the surface processed layer 153 is depressed in the concave surface form toward the upper surface of the plated layer 152 in the concave surface form.

In the modification, the upper surface and the side surface of the plated layer 152 are covered with the surface processed layer 153 and accordingly, for example, when the electrode 210 of the semiconductor chip 200 is joined to the connection terminal 150 with the solder 210a, it is possible to increase wettability of the solder 210a.

### Second Embodiment

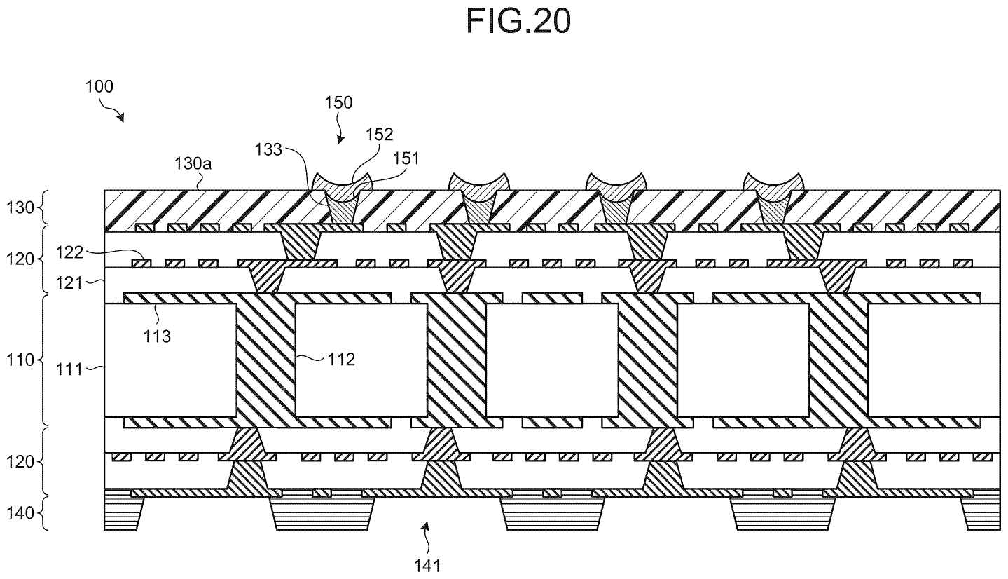

FIG. 20 is a diagram illustrating a configuration of the wiring board 100 according to the second embodiment. In the second embodiment, the same parts as those of the first embodiment are denoted with the same reference numerals and redundant description thus will be omitted.

As illustrated in FIG. 20, the wiring board 100 according to the second embodiment is different from the first embodiment in the structure of the outermost insulating layer 130 and the structure of the pad 151 of the connection terminal 150. Specifically, the outermost insulating layer 130 is a single-layer structure and covers the interconnection layer 122 on the surface of the multilayer interconnection structure 120. The thickness of the outermost insulating layer 130 is, for example, around 20 to 40 μm. In the positon in which a semiconductor chip is mounted, the openings 133 are formed in the outermost insulating layer 130.

The pad 151 is an electrode serving as the main part of the connection terminal 150 and is embedded in the outermost insulating layer 130. The pad 151 is formed in the opening 133 of the first insulating layer 131 by, for example, copper (Cu) electrolytic plating and is connected to the interconnection layer 122 of the multilayer interconnection structure 120. An end face (upper surface) of the pad 151 is exposed on a surface 130a of the outermost insulating layer 130. The end face of the pad 151 is depressed in a concave surface form to a position lower than the surface 130a of the outermost insulating layer 130 and the periphery of the end face of the pad 151 is higher than the center.

In the second embodiment, as in the first embodiment, because the plated layer 152 is formed along the end face of the pad 151 that is depressed in the concave surface form, the upper surface of the plated layer 152 is depressed in the concave surface form toward the end face of the pad 151 in the concave surface form. This makes it possible to inhibit occurrence of a solder bridge caused by solder.

In the second embodiment, the outermost insulating layer is a single-layer structure and therefore has a thickness smaller than that of the outermost insulating layer 130 that is a double-layered structure. This makes it possible to further making the wiring board 100 thinner.

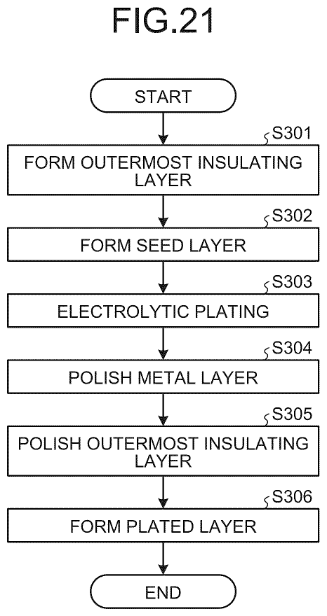

A process of forming the connection terminals 150 will be described with reference to FIG. 21 next. FIG. 21 is a flowchart illustrating a connection terminal forming process according to the second embodiment. For example, the case where the outermost insulating layer 130 and the connection terminals 150 are formed on the interconnection layer 122 that is the top layer of the multilayer interconnection structure 120 as illustrated in FIG. 20 will be described here.

After the multilayer interconnection structure 120 is layered on the upper surface of the core board 110, the interconnection layer 122 that is the top layer of the multilayer interconnection structure 120 is covered with the outermost insulating layer 130 (step S301). For example, as illustrated in FIG. 22, the opening 133 is formed in the outermost insulating layer 130. FIG. 22 is a diagram illustrating a specific example of an outermost insulating layer forming process. When the outermost insulating layer 130 is formed using photosensitive resin, it is possible to form the opening 133 by exposure and development. When the outermost insulating layer 130 is formed using non photosensitive resin, it is possible to form the opening 133 by laser processing. The interconnection layer 122 is exposed on the bottom surface of the opening 133. The thickness of the outermost insulating layer 130 is, for example, around 20 to 40 μm.

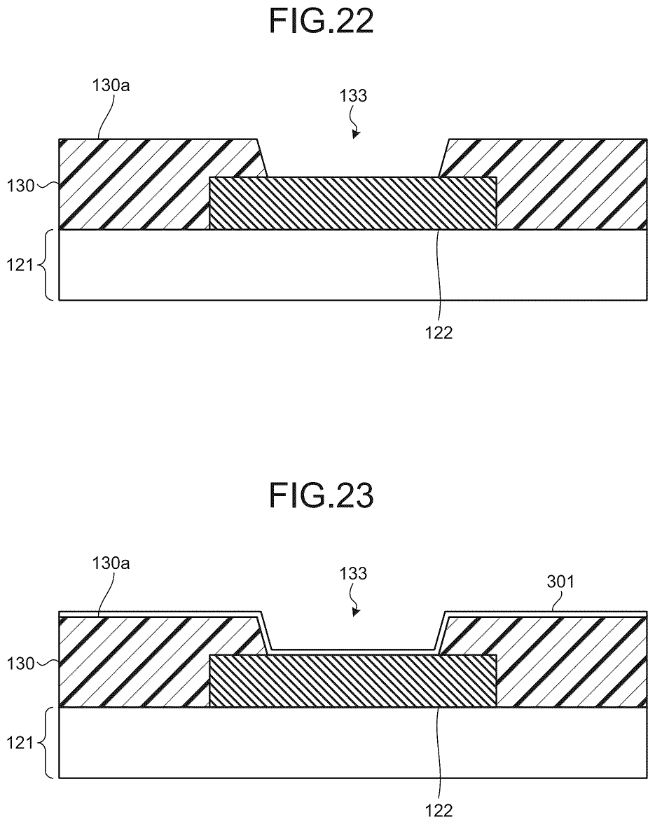

In this state, a seed layer is formed on the surface 130a of the outermost insulating layer 130 (step S302). In other words, for example, as illustrated in FIG. 23, the seed layer 301 is formed on the surface 130a of the outermost insulating layer 130 and over the surface of the interconnection layer 122 that is exposed in the opening 133 by, for example, electroless copper plating or copper sputtering. FIG. 23 is a diagram illustrating a specific example of a seed layer forming process. The thickness of the seed layer 301 is, for example, around 0.01 to 0.4 μm.

For example, electrolytic plating is performed and accordingly a metal layer 151A is formed on the seed layer 301 (step S303). Specifically, for example, electrolytic copper plating is performed using a copper sulfate plating solution and accordingly copper precipitates over the entire upper surface of the seed layer 301 and, for example, as illustrated in FIG. 24, the metal layer 151A is formed over the entire upper surface of the seed layer 301. At that time, the metal layer 151A fills the inside of the opening 133 and extends around the opening 133 on the surface 130a of the outermost insulating layer 130. FIG. 24 is a diagram illustrating a specific example of an electrolytic plating process.

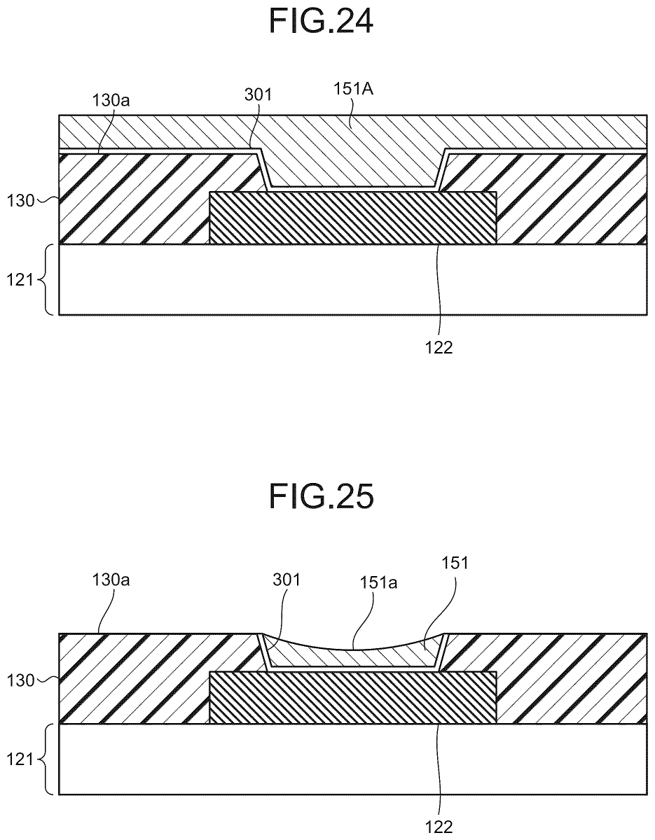

After the metal layer 151A is formed, the metal layer 151A is polished entirely from the upper surface of the metal layer 151A, for example, by CMP (step S304). Specifically, the metal layer 151A is polished until the surface 130a of the outermost insulating layer 130 is exposed, for example, by CMP using a chemical polishing solution, such as a hydrogen peroxide solution. Accordingly, the portion of the metal layer 151A that is positioned on the surface 130a of the outermost insulating layer 130 is polished and the metal layer 151A remains in the opening 133 and, for example, as illustrated in FIG. 25, the pad 151 that connects to the interconnection layer 122 via the seed layer 301 is formed. FIG. 25 is a diagram illustrating a specific example of a metal layer polishing process. Note that the seed layer 301 on the surface 130a of the outermost insulating layer 130 is polished and removed together with the metal layer 151A on the surface 130a of the outermost insulating layer 130.

In the process of polishing the metal layer 151A, in parallel with formation of the pad 151, the end face (upper surface) 151a of the pad 151 that is exposed on the surface 130a of the outermost insulating layer 130 is polished further downward with respect to the surface 130a of the outermost insulating layer 130. Accordingly, the end face 151a of the pad 151 is depressed in the concave surface form to a position lower than the surface 130a of the outermost insulating layer 130. The periphery of the end face 151a of the pad 151 is positioned on the same place as that of the surface 130a of the outermost insulating layer 130. The end face 151a of the pad 151 makes contact with the second insulating layer 132 via the seed layer 301 at the periphery. Because of the preceding process, the pads 151 that are embedded in the outermost insulating layer 130 are obtained.

After the pads 151 are formed, the surface 130a of the outermost insulating layer 130 is polished by, for example, CMP (step S305) and accordingly the residue of the metal layer 151A remaining on the surface 130a of the outermost insulating layer 130 is removed. Thereafter, the plated layer 152 that covers the end face 151a of the pad 151 is formed, for example, as illustrated in FIG. 26 by, for example, non-electrolytic plating using, metal, such as nickel (Ni), as a material (step S306). Accordingly, the connection terminal 150 that connects to the interconnection layer 122 that is the top layer of the multilayer interconnection structure 120 and that includes the pad 151 and the plated layer 152 is formed. FIG. 26 is a diagram illustrating a specific example of a plated layer forming process. The thickness of the plated layer 152 can be, for example, around 1 μm to 10 μm.

In formation of the plated layer 152, metal, such as nickel, isotropically precipitates and grows on the end face 151a of the pad 151. The plated layer 152 thus is formed along the end face 151a of the pad 151 that is depressed in the concave surface form and the upper surface 152a of the plated layer 152 is depressed in the concave surface form toward the end face 151a of the pad 151 in the concave surface form. Accordingly, when the semiconductor chip 200 is mounted, the solder 210a that is supplied to the plated layer 152 of the connection terminal 150 is supplemented on the upper surface 152a of the plated layer 152 that is depressed in the concave surface form and a flow-out of the solder 210a to the outside of the plated layer 152 tends not to occur. As a result, the connection terminals 150 that are adjacent to each other tend not to make conduction via the solder 210a, which makes it possible to inhibit occurrence of a solder bridge caused by the solder 210a.

In formation of the plated layer 152, metal, such as nickel, precipitates and grows not only on the end faces 151a of the pads 151 but also on the surface 130a of the outermost insulating layer 130 that is positioned around the end faces 151a of the pads 151. The periphery of the end faces 151a of the pads 151 are positioned on the same plane as that of the surface 130a of the outermost insulating layer 130 and therefore the plated layer 152 is formed also on the surface 130a of the outermost insulating layer 130 over the periphery of the end faces 151a of the pads 151. For this reason, the plated layer 152 is formed astride the outermost insulating layer 130 and the pad 151 in a plane view. In other words, the side surface of the plated layer 152 is positioned outward with respect to the periphery of the end face 151a of the pad 151. Accordingly, the end face 151a of the pad 151 and the surface 130a of the outermost insulating layer 130 that is positioned around the end face of the pad 151 are continuously covered with the plated layer 152. This increases the strength of adhesion between the plated layer 152 and the end face of the pad 151, which makes it possible to inhibit the plated layer 152 from peeling from the end face 151a of the pad 151.

In the second embodiment, the insulating layer (the outermost insulating layer 130 serving as an example) covers the interconnection layer (the interconnection layer 122 serving as an example) and has the opening (the opening 133 serving as an example) that penetrates to the interconnection layer. The pad (the pad 151 serving as an example) is formed in the opening of the insulating layer and connects to the interconnection layer. The insulating layer thus is a single-layer structure and it is thus possible to inhibit occurrence a solder bridge caused by solder and further making the wiring board thinner.

### Modification of Second Embodiment

In the wiring board 100 according to the second embodiment, the upper surface and the side surface of the plated layer 152 may be covered with the surface processed layer 153 as in the first embodiment. Accordingly, for example, when the electrode 210 of the semiconductor chip 200 is joined to the connection terminal 150 with the solder 210a, it is possible to increase wettability of the solder 210a.

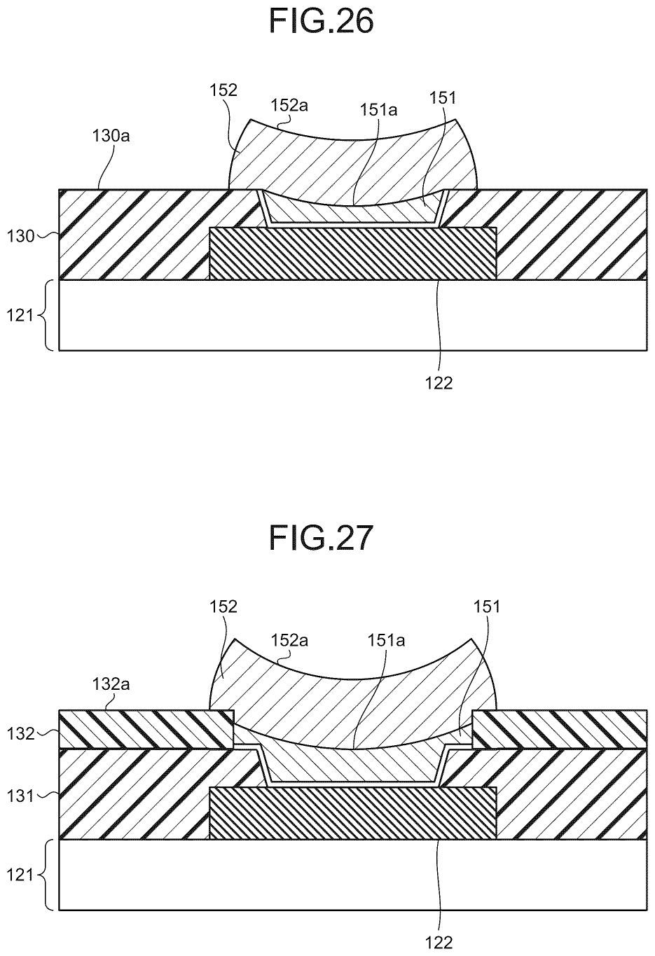

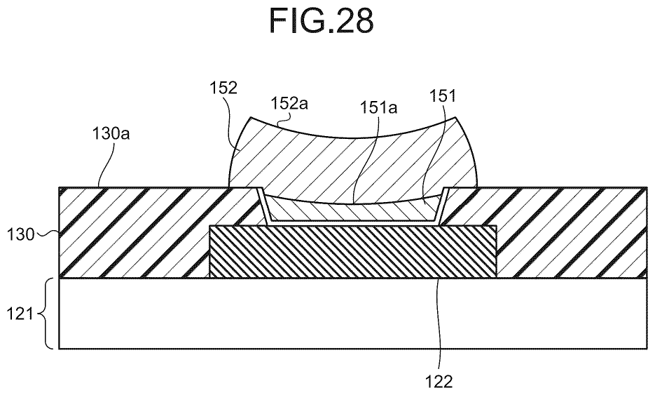

The case where the periphery of the end face of the pad 151 is positioned on the same plane as that of the surface 132a of the second insulating layer 132 has been described; however, as illustrated in FIG. 27 and FIG. 28, the periphery of the end face of the pad 151 may be positioned in a position lower than the surface 132a of the second insulating layer 132. Accordingly, compared to the case where the periphery of the end face of the pad 151 is positioned on the same plane as that of the surface 132a of the second insulating layer 132, the level of the end face of the pad 151 with respect to the surface 132a of the second insulating layer 132 is low. For this reason, the upper surface of the plated layer 152 is depressed deeper in the concave surface form toward the end face of the pad 151 in the concave surface form and, in the case where solder for joining the semiconductor chip to the connection terminal 150 is supplied, a flow-out of the solder to the outside of the plated layer 152 further tends not to occur. As a result, the connection terminals 150 that are adjacent to each other tend not to make conduction via the solder, which makes it possible to further inhibit occurrence of a solder bridge caused by the solder.

According to a mode of the wiring board disclosed herein, an effect that it is possible to inhibit occurrence of a solder bridge caused by solder is enabled.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring board comprising:
an insulating layer; and
a connection terminal that is formed on a surface of the insulating layer,
wherein the connection terminal includes
a pad that is embedded in the insulating layer; and
a plated layer that covers an end face of the pad that is exposed on the surface of the insulating layer,
the end face of the pad is depressed in a concave surface form to a position lower than the surface of the insulating layer, and
a surface of the plated layer on a side opposite to a surface making contact with the end face of the pad is depressed in the concave surface form toward the end face.

2. The wiring board according to claim 1, wherein the end face of the pad has a periphery that is positioned on a same plane as the surface of the insulating layer.

3. The wiring board according to claim 1, wherein the end face of the pad has a periphery that is positioned in a position lower than the surface of the insulating layer.

4. The wiring board according to claim 1, wherein the end face of the pad makes contact with the insulating layer at a periphery.

5. The wiring board according to claim 1, wherein the plated layer is made of nickel.

6. The wiring board according to claim 1, wherein the plated layer is formed astride the insulating layer and the pad in a plane view.

7. The wiring board according to claim 1, wherein
the insulating layer includes
a first insulating layer; and
a second insulating layer that is layered on the first insulating layer,
the first insulating layer covers an interconnection layer and has an opening that penetrates to the interconnection layer, and
the pad is formed in the opening of the first insulating layer and connects to the interconnection layer, protrudes from the opening of the first insulating layer, and is embedded in the second insulating layer at a portion protruding from the opening.

8. The wiring board according to claim 1, wherein
the insulating layer covers an interconnection layer and has an opening that penetrates to the interconnection layer, and
the pad is formed in the opening of the insulating layer and connects to the interconnection layer.

9. The wiring board according to claim 1, wherein the connection terminal further includes a surface processed layer that covers the surface of the plated layer on the side opposite to the surface making contact with the end face of the pad and a side surface of the plated layer.

10. A semiconductor device comprising:
a wiring board; and
a semiconductor chip that is mounted on the wiring board,
the wiring board includes
an insulating layer; and
a connection terminal that is formed on a surface of the insulating layer,
wherein the connection terminal includes
a metal pad that is embedded in the insulating layer; and
a plated layer that covers an end face of the pad that is exposed on the surface of the insulating layer,
the end face of the pad is depressed in a concave surface form to a position lower than the surface of the insulating layer,
a surface of the plated layer on a side opposite to a surface making contact with the end face of the pad is depressed in the concave surface form toward the end face, and
the semiconductor chip is mounted above the connection terminal and an electrode of the semiconductor chip is joined to the connection terminal with solder that is supplied to the plated layer.
